(19) United States
(12) Patent Application Publication
(10) Pub. No.: US 2024/0410722 A1
(43) Pub. Date: Dec. 12, 2024

(54) DETECTION DEVICE

(71) Applicant: Toshiba Tec Kabushiki Kaisha, Tokyo (JP)

(72) Inventor: Sho KOIKE, Sunto Shizuoka (JP)

(21) Appl. No.: 18/423,092

(22) Filed: Jan. 25, 2024

(30) Foreign Application Priority Data
Jun. 9, 2023 (JP) 2023-095573

(51) Int. Cl. G01D 5/24; G16Y 20/10; G16Y 40/60

(52) U.S. Cl. CPC G01D 5/24; G16Y 20/10; G16Y 40/60

(57) ABSTRACT

A detection device for detecting a person near a target object includes an electrode installed proximate to the target object, and a capacitive sensing circuit connected to the electrode and capable of sensing capacitive changes on the electrode. The sensing circuit is configured to acquire a cumulative amount of the capacitive changes in a particular period, determine whether there is a person near the target object based on the cumulative amount, and upon determining that there is a person near the target object, issue a first signal indicating that there is a person near the target object.

### CROSS-REFERENCE TO RELATED APPLICATION(S)

This application is based upon and claims the benefit of priority from Japanese Patent Application No. 2023-095573, filed Jun. 9, 2023, the entire contents of which are incorporated herein by reference.

### FIELD

Embodiments described herein relate generally to a detection device, a method, and a non-transitory computer readable medium.

### BACKGROUND

There is a demand for remotely checking availability and usage history (hereinafter collectively referred to as “usage status”) of a desk in a free address office workspace without assigned seating, a seat in a restaurant, etc. Conventionally, there is a desk or a seat with a human sensor such that its usage status can be checked remotely. The human sensor can detect a person close to a desk or a seat. However, when such a desk or a seat equipped with a human sensor is newly introduced into an office, a restaurant, or the like for the first time, it is often necessary to replace conventional desks and other facilities and systems, and a large amount of cost is incurred. In order to decrease such an installation cost, for example, an IoT (internet of things) device including an infrared human sensor may be installed on a conventional desk. However, the infrared sensor is sensitive to fluctuation in temperature. Therefore, in the method using the infrared human sensor, erroneous detection can occur due to the heat from an air conditioner or sunlight, and thus detection of a person close to a desk or a seat may be inaccurate.

In order to prevent such a decrease in detection accuracy, an IoT device including a capacitance sensor instead of an infrared sensor may be installed on a desk. In general, in a method of detecting a person using a capacitance sensor, the presence or absence of a nearby person is determined based on the absolute value of a measured capacitance value. More specifically, in detecting a person using a capacitance sensor, for example, when the absolute value of the measured capacitance value is equal to or larger than a predetermined threshold value, it is determined that there is a person in proximity. On the other hand, for example, if the absolute value of the measured capacitance value is less than the predetermined threshold value, it is determined that there is no person in the vicinity.

However, generally, the initial value of the capacitance value greatly varies depending on the material and thickness of the desk to which the IoT device is attached. Therefore, appropriate threshold values vary depending on the desk to which the IoT device including the capacitance sensor is attached. In addition, the capacitance value greatly changes not only when there is a nearby person, but also when an object is placed near the desk or when the chair moves. Therefore, in such a conventional method, the absolute value of the capacitance value may exceed a predetermined threshold value even if there is no person in the vicinity. As a result, erroneous detection can still occur, and detection of a person close to a desk or a seat may still be inaccurate.

### SUMMARY OF THE INVENTION

Embodiments of the present invention provide a detection device, a method, and a non-transitory computer readable medium for detecting a nearby person accurately.

In one embodiment, a detection device for detecting a person near a target object, comprises an electrode installed proximate to the target object and a capacitive sensing circuit connected to the electrode and capable of sensing capacitive changes on the electrode. The sensing circuit is configured to acquire a cumulative amount of the cumulative capacitive changes in a particular period, determine whether there is a person near the target object based on the cumulative amount, and upon determining that there is a person near the target object, issue a first signal indicating that there is a person near the target object.

### BRIEF DESCRIPTION OF THE DRAWINGS

FIG. 1 is an external view of a detection device according to an embodiment.

FIG. 2 is a diagram illustrating an internal configuration of a substrate housing of the detection device.

FIG. 3 is a diagram of an installation example of the detection device.

FIG. 4 is a diagram illustrating an example of changes in capacitance values measured by the detection device.

FIG. 5 is a flowchart of an operation of the detection device.

### DETAILED DESCRIPTION

Hereinafter, embodiments will be described in detail with reference to the drawings. Embodiments of the present invention are not limited to the embodiments described below.

The overall configuration of a detection device 1 according to an embodiment will be described. The detection device 1 is an IoT device including a capacitive proximity sensor. However, the detection device 1 is not limited to such an IoT device, and may be, for example, a stand-alone device or a device including a communication interface connected to a network by wire. The capacitive proximity sensor can detect a proximate object by measuring a capacitance value using an electric field and measure the change. The detection device 1 is attached to, for example, a desk. The detection device 1 detects a person using a desk or a seat or chair (hereinafter collectively referred to as a “desk or the like”) in a non-contact manner. The detection device 1 wirelessly connects to a network, and transmits information indicating a detection result to an external device via the network. Here, the external device is, for example, a server or the like that collects information indicating a usage status of the desk or the like.

The detection device 1 includes a capacitive sensor of a self-capacitance type. However, the type of the sensor is not limited to the self-capacitance type, and other types of sensors may be used. The detection device 1 includes a capacitive sensing IC (Integrated Circuit) 124 connected to an electrode and a base having a function of transferring information as an IoT sensor. The detection device 1 outputs a signal to the electrode and calculates a capacitance value based on the change. The detection device 1 further calculates the change amount in the calculated capacitance value, and detects a person close to the desk or the like based on the cumulative value of the calculated change amount.

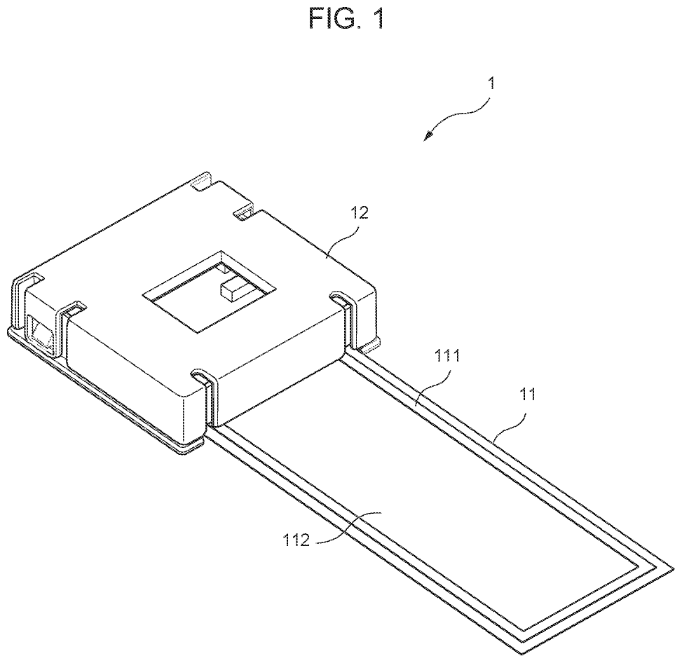

Hereinafter, a configuration example of the detection device 1 will be described in more detail. FIG. 1 is an external view of the detection device 1. As illustrated in FIG. 1, the detection device 1 includes an electrode unit 11 and the substrate housing 12.

The electrode unit 11 includes a copper foil tape 111 and insulating tapes 112. The copper foil tape 111 is used as an electrode of the detection device 1.

In general, a printed circuit board such as a flexible printed circuit (FPC) may be used as an electrode of a conventional detection device. On the other hand, the detection device 1 includes the copper foil tape 111 that can be produced in a manufacturing process simpler than the FPC. Thus, the manufacturing cost of the detection device 1 can be decreased.

Further, in order to detect an object in a non-contact manner using a capacitive proximity sensor, it is necessary to sufficiently increase the size of the electrode. Generally, the size of the electrode with an FPC is approximately 2-3 centimeters wide and the length can be extended to any length. On the other hand, when the copper foil tape 111 is used as an electrode, it is possible to have any length in both the vertical direction and the horizontal direction. Therefore, in the detection device 1 using the copper foil tape 111, an electrode of any size and any shape can be easily formed.

A copper wire or the like may be used instead of the copper foil tape 111. However, since the copper foil tape 111 can be formed thinner than the copper wire and can be easily attached to a desk or the like, it is desirable to use the copper foil tape 111.

The insulating tapes 112 cover the copper foil tape 111 in order to prevent leakage or electric shock. For example, the copper foil tape 111 is covered so as to be sandwiched between two insulating tapes 112. One of the two insulating tapes 112 is further covered with an adhesive tape, for example. As a result, the detection device 1 can be easily installed at an any position such as the top plate of a desk or the bottom surface of a drawer.

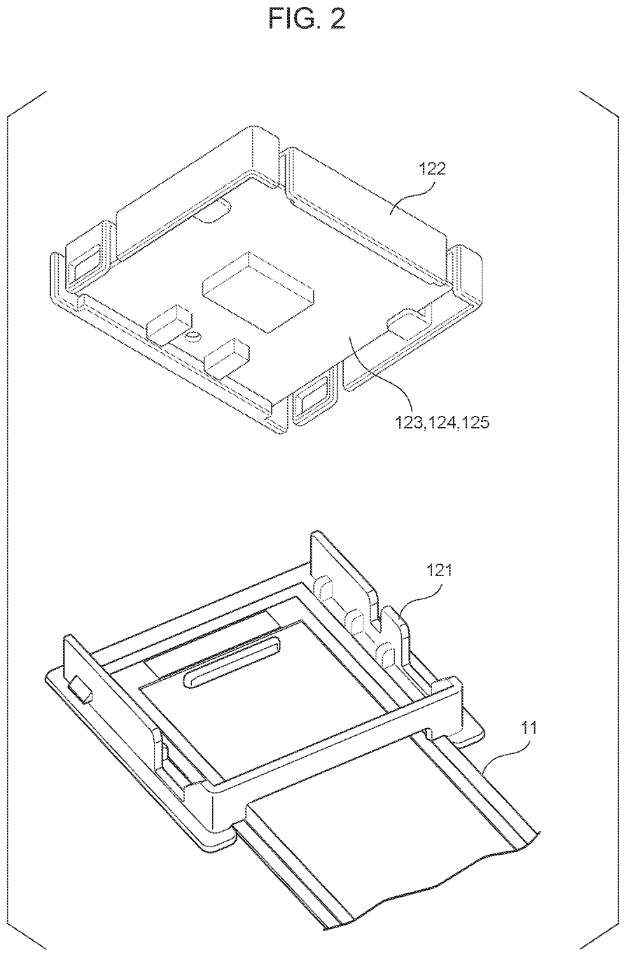

FIG. 2 is a diagram illustrating an internal configuration of the substrate housing 12 of the detection device 1. As illustrated in FIG. 2, the substrate housing 12 includes an upper surface portion 121 that holds the electrode unit 11, and a lower surface portion 122 that incorporates a substrate 123. The substrate 123 includes the capacitive sensing IC 124 and a communication interface 125.

The capacitive sensing IC 124 is connected to the copper foil tape 111 of the electrode unit 11, and generates an electric field for object detection by the copper foil tape 111. The capacitive sensing IC 124 calculates a capacitance value. The capacitive sensing IC 124 further calculates a change amount of the calculated capacitance value, and determines the presence or absence of a person close to a desk or the like based on the calculated cumulative value of the change amount. The capacitive sensing IC 124 outputs information indicating the detection result to the communication interface 125. Since an IoT device is generally required to operate at low power consumption, the capacitive sensing IC 124 measures electric charges at intervals of, for example, about 10 seconds.

The communication interface 125 is a network interface circuit connected to a network for transferring data. The communication interface 125 wirelessly connects to the network, and transmits information indicating the detection result output from the capacitive sensing IC 124 to an external device via the network.

Note that the communication interface 125 can use a communication method defined by any wireless communication standard. For example, when low-power consumption is intended, a communication method defined by a wireless communication standard such as Bluetooth Low Energy or EnOcean can be used. Further, for example, when high-speed communication is intended, a communication method defined by a wireless communication standard such as IEEE802.11ac which is a wireless Local Area Network (LAN) standard can be used. Further, for example, when long-distance communication is intended, a communication method defined by a wireless communication standard such as LoRa, Wi-Fi HaLow can be used.

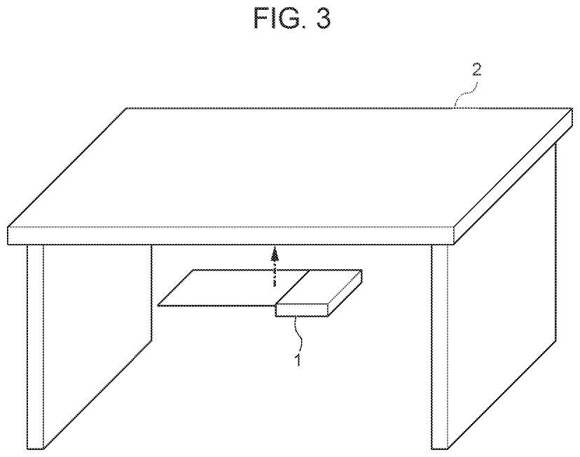

FIG. 3 is a diagram illustrating an installation example of the detection device 1. As shown in FIG. 3, the detection device 1 is attached to the lower surface of the top plate of a desk 2 by, for example, the above-described adhesive tape covering the insulating tape 112. Accordingly, the detection device 1 can detect a thigh of a person who is using the desk 2 and sitting on the chair (not shown) or his or her upper arm on the desk 2.

In the case of a desk 2 provided with a drawer on the lower surface of the top plate, the detection device 1 may be attached to the lower surface of the drawer. In addition, the detection device 1 may be attached to the inside of the leg portion of the desk 2. Further, the detection device 1 may be installed on the side surface of the screening panel of the desk 2 or the side surface of a sleeve box of the desk 2. Further, the detection device 1 may be attached to an object other than the desk 2, for example, a side desk (not shown).

Hereinafter, a detection algorithm used for determining the presence or absence of a person close to the desk 2 or the like will be described.

In a conventional detection process using a capacitive proximity sensor, determination is generally performed based on an absolute value of a measured capacitance value. For example, a conventional capacitive proximity sensor determines that there is a nearby person when the absolute value of the measured capacitance is equal to or greater than a predetermined threshold value. In addition, in a case where the absolute value of the measured capacitance is less than the predetermined threshold value, the conventional capacitive proximity sensor determines that there is no adjacent person. In general, however, the initial value of the capacitance value varies greatly depending on the material, thickness, and the like of a desk to which the sensor is attached, and appropriate threshold values are different from each other. In addition, even when an object other than a person approaches, the capacitance value greatly changes. As a result, erroneous detection may occur, and the detection accuracy may deteriorate.

On the other hand, the detection device 1 determines the presence or absence of a nearby person based on the amount of the fluctuation of the capacitance value, not the absolute value of the capacitance value. Here, the amount of the fluctuation corresponds to the cumulative value of the change amount of the capacitance value for each measurement period. For example, when a moving object such as a person or an animal is close to a capacitive proximity sensor, it is difficult for the person or the animal to be completely stationary, and therefore, a slight movement occurs, and the capacitance value changes finely. On the other hand, when a non-moving object such as an industrial product is in proximity to the capacitive proximity sensor, the capacitance value does not change at all. The detection device 1 can determine the presence or absence of such fine changes in the capacitance value by calculating the cumulative value of the change amount of the capacitance value. The detection device 1 determines the presence or absence of a person close to the desk 2 or the like based on the cumulative value of the change amount of the capacitance value.

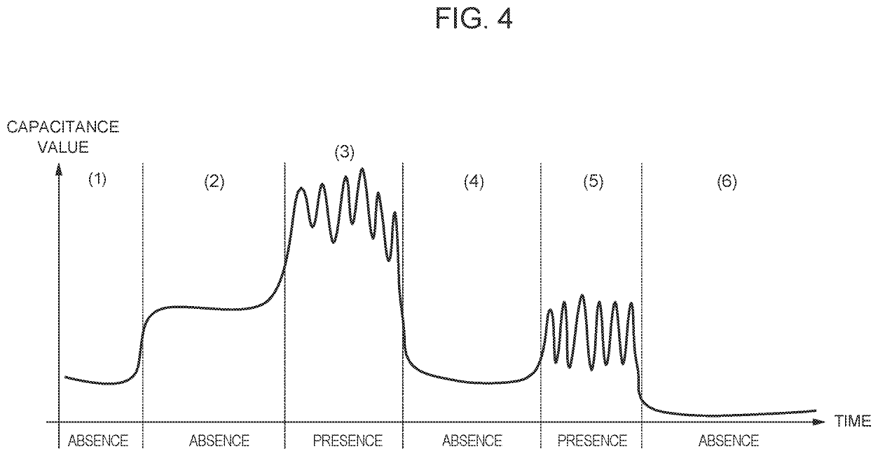

FIG. 4 is a diagram illustrating an example of changes in capacitance values measured by the detection device 1. In the graph shown in FIG. 4, the vertical axis represents a capacitance value, and the horizontal axis represents time. It is assumed that each of the periods (1) to (6) shown in FIG. 4 is a period that is sufficiently longer than a predetermined interval at which the capacitive sensing IC 124 measures a capacitance value. The length of each of the periods (1) to (6) may be identical unlike the example of FIG. 4.

For example, in the period (1) in FIG. 4, the capacitance value hardly changes. In such a case, since the cumulative value of the change amount in the capacitance value becomes a relatively small value, the detection device 1 determines that there is no person close to the desk 2 or the like (i.e., absence). Next, in the period (2) in FIG. 4, the capacitance value increases from the previous period (1), but the capacitance value hardly changes once the capacitance value increases. In such a case, since the cumulative value of the change amount in the capacitance value becomes a relatively small value, the detection device 1 determines that there is no person close to the desk 2 or the like (i.e., absence).

Note that, as in the period (2), when the state is substantially constant without numerical fluctuation in a state in which the capacitance value is increased, there may be a case in which, for example, something that does not move is placed in the vicinity of the desk 2 (for example, above or below the desk 2) or a chair is moved. In the case of a conventional capacitive proximity sensor that determines the presence or absence of a nearby person based on the absolute value of the capacitance value, when the capacitance value is in an increased state as in the period (2), it can be erroneously determined that there is a nearby person (i.e., presence).

Next, in the period (3) in FIG. 4, after the capacitance value further increases from the period (2) one before, the capacitance value also fluctuates finely during the period due to numerical vibration. In such a case, since the cumulative value of the change amount of the capacitance value becomes a relatively large value, the detection device 1 determines that there is a person close to the desk 2 or the like (i.e., presence). Next, in the period (4) in FIG. 4, the capacitance value decreases from the previous period (3), but the capacitance value hardly changes after the capacitance value decreases once. In such a case, since the cumulative value of the change amount in the capacitance value becomes a relatively small value, the detection device 1 determines that there is no person close to the desk 2 or the like (i.e., absence).

Next, the period of (5) in FIG. 4, while maintaining the state of a relatively small capacitance value as in the previous period of (4), the capacitance value during the period is finely fluctuated numerically vibrating. In such a case, since the cumulative value of the change amount of the capacitance value becomes a relatively large value, the detection device 1 determines that there is a person close to the desk 2 or the like (i.e., presence).

In the case of a conventional capacitive proximity sensor that determines the presence or absence of a person in proximity based on the absolute value of the capacitance value, even if the capacitance value is finely changed due to a numerical vibration as in the period (5), the absolute value of the capacitance value is likely to be erroneously determined as the absence of a person in proximity because a small value persists throughout the period.

Next, in the period (6) in FIG. 4, the capacitance value decreases from the previous period (5), but the capacitance value hardly changes after the capacitance value decreases once. In such a case, since the cumulative value of the change amount in the capacitance value becomes a relatively small value, the detection device 1 determines that there is no person close to the desk 2 or the like (i.e., absence). Note that, as in the period (6), when the capacitance value is constant without numerical vibration in a state of being lowered to a value close to zero, there is a case where all the objects are removed from the vicinity of the desk 2.

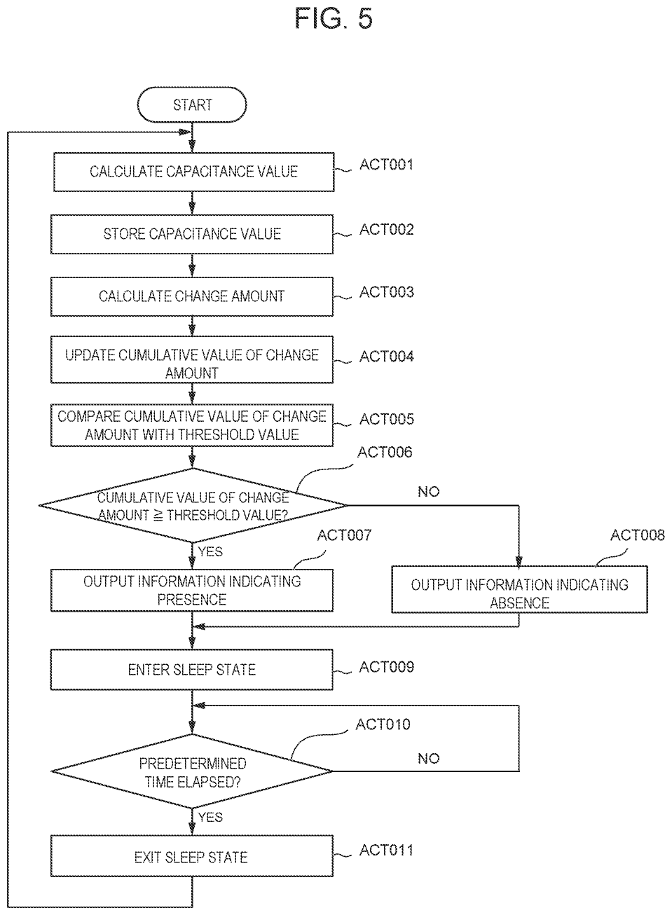

Hereinafter, an example of the operation of the detection device 1 will be described with reference to FIG. 5. The operation of the detection device 1 illustrated in the flowchart of FIG. 5 is started, for example, when the detection device 1 is powered on.

The capacitive sensing IC 124 measures a capacitance value through the electrode unit 11 (ACT001). The capacitive sensing IC 124 stores the capacitance value in, for example, a memory (not shown) provided on the substrate 123 (ACT002). The capacitive sensing IC 124 refers to the memory and reads a capacitance value measured previously. The capacitive sensing IC 124 calculates a variation of the capacitance value by calculating a change amount between the current capacitance value and the previous capacitance value (ACT003).

The capacitive sensing IC 124 refers to the memory and reads a cumulative value of the change amount in the capacitance value up to the previous time (hereinafter, referred to as “cumulative value of change”). The capacitive sensing IC 124 updates the cumulative value of change amount. For example, the capacitive sensing IC 124 multiplies the cumulative value change amount read by 0.8, multiplies the change amount of the capacitance value calculated this time by 0.2, and sums the values of both. Then, the capacitive sensing IC 124 sets the summed value as a new cumulative value of change amount (ACT004). In the first measurement of the capacitance value, since the cumulative value of the change amount has not yet been recorded, the measured capacitance value is recorded as the cumulative value of the change amount as it is. The steps from ACT001 to ACT004 can be repeatedly performed within a particular time period.

After the particular time period elapses, the capacitive sensing IC 124 compares the cumulative value of change amount with a predetermined threshold value (ACT005). When the cumulative value of change amount is equal to or larger than the threshold value (ACT006, YES), the capacitive sensing IC 124 determines that a person close to the desk 2 or the like is present, and outputs information indicating that the person is present to the communication interface 125 (ACT007). On the other hand, when the cumulative value of change amount is smaller than the threshold value (ACT006, NO), the capacitive sensing IC 124 determines that there is no person close to the desk 2 or the like (i.e., absence), and outputs information indicating that there is no person to the communication interface 125 (ACT008). The communication interface 125 wirelessly connects to the network, and transmits information indicating the detection result obtained from the capacitive sensing IC 124 to an external device via the network.

Next, the capacitive sensing IC 124 enters a sleep state (ACT009). The capacitive sensing IC 124 is in the sleep state until a predetermined time elapses (ACT010, NO). When the predetermined time has elapsed (ACT010, YES), the capacitive sensing IC 124 returns from the sleep state and resumes the process from the above-described ACT001. Thereafter, the process illustrated in the flowchart of FIG. 5 is repeatedly executed until, for example, the detection device 1 is powered off.

As described above, the detection device 1 is an IoT device including a capacitive proximity sensor. The detection device 1 includes an electrode unit 11 and a capacitive sensing IC 124. The capacitive sensing IC 124 generates an electric field for detecting an object by the electrode unit 11. The capacitive sensing IC 124 measures the capacitance value of the electrode unit 11. The capacitive sensing IC 124 calculates the change amount in the calculated capacitance value, and determines the presence or absence of a person close to the desk 2 or the like based on the cumulative value of the calculated change amount.

With such a configuration, the detection device 1 can detect a slight movement of a person close to the desk 2 even when that person is stationary, and can prevent erroneous detection of a non-moving object such as an industrial product. Thus, the detection device 1 can detect a nearby person with high accuracy.

As described above, in general, the initially measured capacitance value varies greatly depending on the material, thickness, and the like of the desk to which the capacitive proximity sensor is attached, and appropriate threshold values are different from each other. Therefore, in the conventional capacitive proximity sensor, erroneous detection may occur. On the other hand, since the detection device 1 has a configuration in which the detection is performed based on the cumulative value of the change amount of the capacitance value instead of the determination based on the absolute value of the capacitance value, there is an advantage that an appropriate threshold value is not affected by the material, thickness, and the like of the desk. Thus, the detection device 1 can reduce the occurrence of erroneous detection.

Further, as described above, the capacitance value greatly changes not only in the case where there is a close person, but also in the case where an object is placed in the vicinity of the desk or in the case where the chair moves. As a result, the absolute value of the capacitance value may exceed a predetermined threshold value even if there is no nearby person. In this case, in the conventional proximity sensor of capacitive type, since the detection is made on the basis of the absolute value of the capacitance value, there is a possibility that erroneous detection occurs when there is a close person. On the other hand, the detection device 1 has a configuration in which the determination is not performed based on the absolute value of the capacitance value, but is performed based on the cumulative value of the change amount in the capacitance value. Therefore, in the detection device 1, in the case of a gradual change in the capacitance value without numerical fluctuation, it is determined that there is no person in the vicinity. As a result, the detection device 1 determines that there is no person in proximity in the case of a gradual change in the capacitance value caused by the movement of an industrial product such as a chair, for example, and thus the occurrence of erroneous detection is prevented.

Further, as described above, the copper foil tape 111 that can be produced in a simpler manufacturing process is used as the electrode of the detection device 1. Since the production cost of the copper foil tape 111 can be kept lower, and the price of the detection device 1 can also be kept lower. In addition, the copper foil tape 111 can be formed thinner than, for example, a copper wire or the like, and can be easily attached to the desk 2 or the like. Accordingly, the detection device 1 can further reduce the installation cost and the installation space.

According to the above-described embodiments, the detection device 1 includes a capacitive sensing IC 124, which measures a capacitance value that varies in response to an entry of an object into an electric field. The capacitive sensing IC 124 determines whether there is a nearby person based on the change amount in the capacitance value measured by the sensor.

In the detection device 1 described above, the capacitive sensing IC 124 may determine that there is a nearby person when the cumulative value of the change amount of the capacitance value in the predetermined period is equal to or larger than the threshold value.

In the detection device 1 described above, the capacitive sensing IC 124 may determine that there is a nearby person when the capacitance value changes with the numerical vibration.

The detection device 1 may further include an electrode unit 11. The electrode unit 11 generates an electric field. The electrode unit 11 includes a copper foil tape 111.

In the detection device 1 described above, the substrate housing 12 may be installed on the lower surface of the top plate or a drawer of the desk 2, the side surface of the screening panel of the desk 2, or the side surface of the sleeve box of the desk 2.

Some or all of the functions performed by the substrate 123 or the capacitive sensing IC 124 in the above-described embodiments may be performed by a processor such as a central processing unit (CPU) for a computer. In this case, a program for performing this function may be recorded in a computer-readable recording medium, and the program recorded in the recording medium may be copied to a computer system and executed. Here, the “computer system” includes hardware such as an operating system (OS) and a peripheral device. In addition, the “computer-readable recording medium” refers to a portable medium such as a flexible disk, a magneto-optical disk, or a ROM, a CD-ROM, or a storage device such as a hard disk built in a computer system. Further, the “computer-readable recording medium” may include a medium that stores a program such as a volatile memory inside a computer system serving as a server or a client. Further, the above-described program may have one or more of the above-described functions, and another program pre-recorded in a computer system may have the other functions.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A detection device for detecting a person near a target object, comprising:
an electrode installed proximate to the target object; and
a capacitive sensing circuit connected to the electrode and capable of sensing capacitive changes on the electrode, wherein the sensing circuit is configured to:
acquire a cumulative amount of the capacitive changes in a particular period,
determine whether there is a person near the target object based on the cumulative amount, and
upon determining that there is a person near the target object, issue a first signal indicating that there is a person near the target object.

2. The detection device according to claim 1, wherein the sensing circuit is configured to:
determine whether the cumulative amount is greater than or equal to a threshold value, and
determine that there is a person near the target object when the cumulative amount is greater than the threshold value.

3. The detection device according to claim 1, wherein the sensing circuit is configured to, upon determining that there is not a person near the target object, issue a second signal indicating that there is not a person near the target object.

4. The detection device according to claim 1, further comprising:
a wireless communication interface, wherein
the sensing circuit is configured to control the wireless communication interface to transmit the first signal to an external device.

5. The detection device according to claim 1, wherein the electrode is formed of a cupper foil tape.

6. The detection device according to claim 5, further comprising:
an insulating tape on the cupper foil tape.

7. The detection device according to claim 6, an adhesive is applied to a surface of the insulating tape.

8. The detection device according to claim 1, wherein the sensing circuit is configured to enter a sleep state after issuing the first signal.

9. The detection device according to claim 1, wherein the sensing circuit is configured to exit the sleep state after a particular time elapses.

10. The detection device according to claim 1, further comprising:
a housing in which the sensing circuit is stored and having a side surface from which the electrode extends toward a first direction.

11. A method performed by a detection device that includes an electrode installed proximate to a target object and a capacitive sensing circuit connected to the electrode and capable of sensing capacitive changes on the electrode, the method comprising:
acquiring a cumulative amount of the capacitive changes in a particular period;
determining whether there is a person near the target object based on the cumulative amount; and
upon determining that there is a person near the target object, issuing a first signal indicating that there is a person near the target object.

12. The method according to claim 11, wherein determining includes:
determining whether the cumulative amount is greater than or equal to a threshold value, and
determining that there is a person near the target object when the cumulative amount is greater than the threshold value.

13. The method according to claim 11, further comprising:
upon determining that there is not a person near the target object, issuing a second signal indicating that there is not a person near the target object.

14. The method according to claim 11, further comprising:
transmitting the first signal to an external device.

15. The method according to claim 11, wherein the electrode is formed of a cupper foil tape.

16. The method according to claim 15, wherein the cupper foil tape is covered by an insulating tape.

17. The method according to claim 16, wherein an adhesive is applied to a surface of the insulating tape.

18. The method according to claim 11, further comprising:
entering a sleep state after the first signal is issued.

19. The method according to claim 11, further comprising:
exiting the sleep state after a particular time elapses.

20. A non-transitory computer readable medium storing a program causing a computer to execute a method for detecting a person near a target object, the method comprising:
sensing capacitive changes on an electrode for capacitive sensing installed proximate to the target object;
acquiring a cumulative amount of the capacitive changes in a particular period; and
determining that there is a person near the target object based on the cumulative amount, and issuing a first signal indicating that there is a person near the target object.
